(19) United States
(12) Patent Application Publication
(10) Pub. No.: US 2026/0148777 A1
(43) Pub. Date: May 28, 2026

(54) MEMORY DEVICE AND METHOD OF OPERATION THEREOF

(71) Applicant: SAMSUNG ELECTRONICS CO., LTD., Suwon-si (KR)

(72) Inventors: Yonghyuk CHOI, Suwon-si (KR); Doohyun KIM, Suwon-si (KR); Yohan LEE, Suwon-si (KR); Kwangho CHOI, Suwon-si (KR)

(73) Assignee: SAMSUNG ELECTRONICS CO., LTD., Suwon-si (KR)

(21) Appl. No.: 19/338,699

(22) Filed: Sep. 24, 2025

(30) Foreign Application Priority Data
Nov. 27, 2024 (KR) 10-2024-0172238

(51) Int. Cl. G11C 16/34; G11C 16/04; G11C 16/10; G11C 16/16

(52) U.S. Cl. CPC G11C 16/3427; G11C 16/0483; G11C 16/10; G11C 16/16

(57) ABSTRACT

A memory device includes a common source line, a first cell region that controls a connection between the common source line and string selection lines, and a dummy cell region including one or more dummy word lines to which dummy elements are connected. The dummy cell region is disposed in the first cell region or between the common source line and the first cell region.

### CROSS-REFERENCE TO RELATED APPLICATION

This application claims the benefit of Korean Patent Application No. 10-2024-0172238, filed on Nov. 27, 2024, in the Korean Intellectual Property Office, the disclosure of which being incorporated by reference herein in its entirety.

### BACKGROUND

Example embodiments relate to a memory device and a method of operation thereof.

Based on consumer demands for the performance and size of electronic systems storing data, a degree of integration of semiconductor devices is increasing. Accordingly, the sophistication of semiconductor processes and design is required, and in particular, a design technology is demanded for ensuring not only performance but also high reliability and efficient operation of high-density semiconductor devices.

### SUMMARY

It is an aspect to provide a memory device in which a threshold voltage of a transistor is coded to minimize data interference and a method of operation of the memory device for coding the threshold voltage of the transistor to minimize data interference.

According to an aspect of one or more embodiments, there is provided a memory device comprising a common source line; a first cell region configured to control a connection between the common source line and a plurality of string selection lines; and a dummy cell region including one or more dummy word lines to which a plurality of dummy elements are connected. The dummy cell region is disposed in the first cell region or between the common source line and the first cell region.

According to another aspect of one or more embodiments, there is provided a method of operation of a memory device, the method comprising performing an erase operation for data stored in a first cell region including one or more ground selection lines, a second cell region including a plurality of main word lines, and a dummy cell region including one or more dummy word lines; determining a set voltage to apply to each of a plurality of word lines including the one or more ground selection lines, the plurality of main word lines, and the one or more dummy word lines based on a location level of the each of the plurality of word lines with respect to a substrate; and performing a program operation of applying the set voltage during a setup period of each of the plurality of word lines. The dummy cell region is disposed in the first cell region or between a common source line and the first cell region.

According to yet another aspect of one or more embodiments, there is provided a memory device comprising a memory cell array including a plurality of cell strings that are stacked on a substrate and connected to a common source line in parallel; and a control logic configured to perform control of the memory cell array. The memory cell array comprises the common source line, and a plurality of word lines including one or more ground selection lines included in a first cell region, the one or more ground selection lines being configured to control a connection between the common source line and a plurality of string selection lines, a plurality of main word lines included in a second cell region, the plurality of main word lines being configured to store data, and one or more dummy word lines included in a dummy cell region disposed between the common source line and the first cell region, the plurality of word lines being configured to connect elements among a plurality of elements included in the plurality of cell strings that are disposed at location levels with respect to the substrate to each other. The control logic is configured to apply a voltage of a size determined based on a location level of each of the plurality of word lines with respect to the substrate to the each of the plurality of word lines.

### BRIEF DESCRIPTION OF THE FIGURES

These and/or other aspects will become apparent and more readily appreciated from the following description of example embodiments, taken in conjunction with the accompanying drawings, in which:

FIGS. 1 and 2 are diagrams showing a memory device according to example embodiments;

FIG. 3 is a diagram for illustrating a memory cell array according to example embodiments;

FIG. 4 is a circuit diagram illustrating a plurality of cell strings according to example embodiments;

FIGS. 5A and 5B are plan views showing a memory device according to example embodiments;

FIG. 6 is a diagram for illustrating a method of applying a voltage to a memory device according to example embodiments;

FIGS. 7A, 7B, 8A, 8B, 9A, and 9B are diagrams for illustrating a method of applying a voltage to a memory device according to example embodiments;

FIGS. 10 and 11 are diagrams for illustrating a method of applying a voltage to a memory device according to example embodiments;

FIGS. 12A to 12C are diagrams for illustrating a method of applying a voltage to a memory device based on a threshold voltage according to example embodiments;

FIGS. 13 and 14 are flowcharts for illustrating a method of operation of a memory device according to example embodiments; and

FIG. 15 is a block diagram of a device according to example embodiments.

### DETAILED DESCRIPTION

Terms used in example embodiments are selected from currently widely used general terms when possible while considering the functions in the present disclosure. However, the terms may vary depending on the intention of a person skilled in the art, precedents, the emergence of new technology, and the like. Further, in certain cases, there are also terms arbitrarily selected by the applicant, and in these cases, the meaning will be described in detail in the corresponding description. Therefore, a given term used in the present disclosure is not to be construed simply as its designation but based on the meaning of the term and the overall context of the present disclosure.

Throughout the specification, when a part is described as “comprising” or “including” a component, the part does not exclude another component but may further include another component unless otherwise stated. Further, terms such as “. . . unit,” “. . . part,” and “. . . module” described in the specification mean a unit that processes at least one function or operation, which may be implemented as hardware, software, or a combination thereof. As used in this specification, a phrase of the form “at least one of A, B, or C” includes within its scope “only A”, “only B”, “only C”, “A and B”, “A and C”, “B and C”, and “A, B, and C.”

Hereinafter, example embodiments will be described in detail with reference to the accompanying drawings so that those of ordinary skill in the art to which the present disclosure pertains may easily implement example embodiments. However, the present disclosure may be implemented in multiple different forms and is not limited to the example embodiments described herein.

According to example embodiments, it is possible to provide a semiconductor design method that may prevent the data reliability of a memory device from decreasing due to interference with an adjacent word line in coding a threshold voltage on a word line of the memory device.

Effects of example embodiments are not limited to those described above, and other effects not mentioned herein may be clearly understood by those skilled in the art from the appended claims.

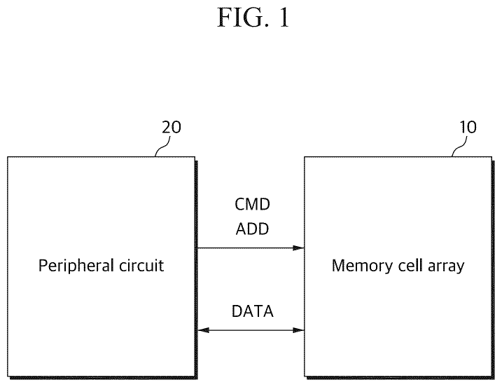

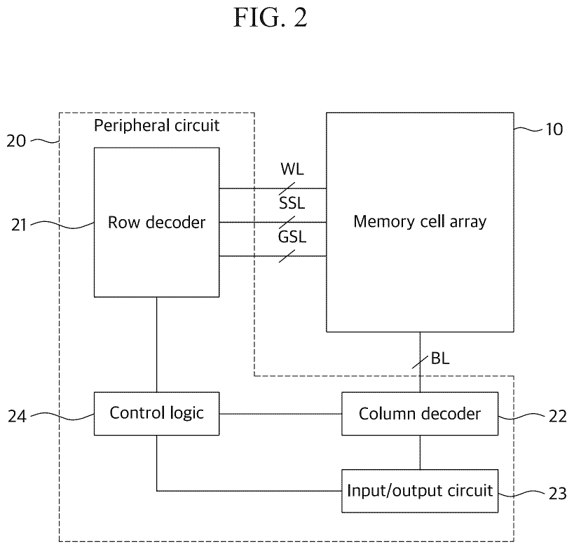

FIGS. 1 and 2 are diagrams showing a memory device according to example embodiments.

Referring to FIG. 1, the memory device according to example embodiments includes a memory cell array 10 in which data is stored and a peripheral circuit 20 for controlling the memory cell array 10.

The memory cell array 10 may perform a program operation, a read operation, or an erase operation in response to a command CMD and an address ADD. The memory cell array 10 may include double data rate synchronous dynamic random-access memory (DDR SDRAM), low power double data rate4 (LPDDR4) SDRAM, graphics double data rate (GDDR) SDRAM, low power DDR (LPDDR), Rambus dynamic random-access memory (RDRAM), and/or flash memory. In some example embodiments, the flash memory may include NAND flash memory.

The peripheral circuit 20 may control operation of the memory cell array 10, and specifically, the peripheral circuit 20 may perform a program operation, a read operation, and/or an erase operation for the memory cell array 10. The peripheral circuit 20 may transmit the command CMD, the address ADD, and data DATA for controlling the memory cell array 10 to the memory cell array 10 in response to a command received from an external device, or may receive the data DATA from the memory cell array 10. In some example embodiments, the address ADD may include a row address and a column address.

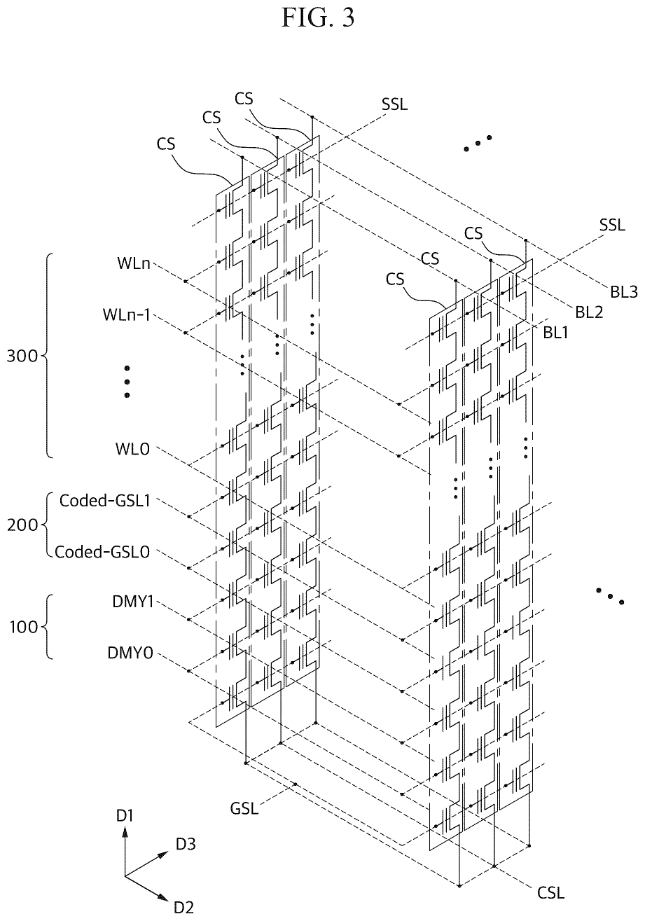

Referring to FIG. 2, the peripheral circuit 20 may include a row decoder 21, a column decoder 22, an input/output circuit 23, and a control logic 24 and may perform control of a plurality of elements included in the memory cell array 10. In some example embodiments, as illustrated in FIG. 3, the plurality of elements may be arranged three-dimensionally, and at least one of the plurality of elements may be connected to at least some of a common source line CSL, a main word line WL, a string selection line SSL, a common ground selection line GSL, a ground selection line Coded-GSL having dispersion of coded threshold voltages, and a dummy word line DMY included in the memory cell array 10. However, the components included in the memory cell array 10 are not limited thereto, and only the components required for understanding the present disclosure are disclosed as examples for convenience of description.

The row decoder 21 may decode a row address inputted from outside of the memory device and transfer voltage to a plurality of word lines WL, Coded-GSL, and DMY corresponding to the row address. In some example embodiments, the peripheral circuit 20 may further include a voltage generator (not shown) that generates a voltage (for example, a program voltage, a read voltage, and/or an erase voltage) for an internal operation of the memory cell array 10 according to the control of the control logic 24.

The plurality of word lines WL, Coded-GSL, and DMY may include the main word line WL, the coded ground selection line Coded-GSL, and the dummy word line DMY, and may further include at least one of the common source line CSL and the common ground selection line GSL.

The column decoder 22 may be connected to the memory cell array 10 through bit lines BL. The column decoder 22 may decode a column address inputted from outside and transmit and receive data through the bit lines BL corresponding to the column address.

The input/output circuit 23 may provide a data transmission path for transmitting and receiving signals such as data, commands, and addresses generated in the memory cell array 10 and the peripheral circuit 20 to and from an external device.

The control logic 24 may perform control of the memory cell array 10. As an example, the control logic 24 may program data in the memory cell array 10 based on a command, an address, and a control signal and may output various control signals (for example, a voltage control signal, a row address, and a column address) for reading data from the plurality of elements of the memory cell array 10. The control logic 24 may regulate a level of voltage generated in the voltage generator (not shown). In addition, the control logic 24 may apply a voltage of a size to the plurality of word lines WL, Coded-GSL, and DMY. The size may be predetermined. In some example embodiments, as described below, the voltage of the size may be a voltage of a size determined based on a location level of each of the plurality of word lines WL, Coded-GSL, and DMY with respect to a substrate.

In an example embodiment, each of the plurality of elements may include a data storage element. In some example embodiments, the plurality of elements may include a plurality of memory cell elements, a plurality of ground selection elements, and a plurality of dummy cell elements. In some example embodiments, the plurality of memory cell elements, the plurality of ground selection elements, and the plurality of dummy cell elements may have an identical cell structure but may be divided from each other according to functions within the memory cell array 10.

The memory cell array 10 may include a first cell region that controls access to the main word line WL and a second cell region that stores data. Specifically, the memory cell array 10 may include the first cell region that controls a connection between the common source line CSL and a plurality of string selection lines SSL and the second cell region including a plurality of main word lines WL in which data is stored. The plurality of memory cell elements may be included in the second cell region, and the plurality of ground selection elements with coded threshold voltages may be included in the first cell region. As an example, one or more ground selection lines Coded-GSL including the plurality of ground selection elements may have dispersion of the coded threshold voltages.

According to an example embodiment, the memory cell array 10 may include a dummy cell region including one or more dummy word lines. In some example embodiments, a plurality of dummy elements may be connected to one or more dummy word lines. Details of the dummy cell region are described below.

FIG. 3 is a diagram for illustrating a memory cell array according to example embodiments.

Referring to FIG. 3, the memory cell array may include a plurality of string arrays arranged three-dimensionally.

The string arrays may include a plurality of cell strings connected to bit lines BL1, BL2, and BL3 in parallel. The plurality of cell strings CS may be formed to be stacked on a substrate to extend along a first direction D1 and connected to each of the bit lines BL1, BL2, and BL3 in parallel. The plurality of cell strings CS may be connected to the common source line CSL in common, and specifically, the plurality of cell strings CS may be connected to the common source line CSL in parallel. In some example embodiments, the first direction D1 may refer to a direction perpendicular to an upper surface of the substrate.

Each of the plurality of cell strings CS may include a plurality of memory cell elements, a plurality of ground selection elements, and a plurality of dummy cell elements stacked in the first direction D1 and connected to each other in series. In some example embodiments, each of the plurality of cell strings CS may further include a string selection element provided between the plurality of memory cell elements and the bit lines BL1, BL2, and BL3.

In an example embodiment, the memory cell array may include string selection lines SSL electrically isolated from each other. The string selection lines SSL may extend along a third direction D3 intersecting the first direction D1 and intersecting a second direction D2. The string selection lines SSL may control the string selection element. In some example embodiments, the second direction D2 may be a direction in which the bit lines BL1, BL2, and BL3 extend. As an example, the third direction D3 may be a direction orthogonal to the first direction D1 and the second direction D2.

Each of a plurality of elements including the string selection element, the memory cell elements, the ground selection elements, and the dummy cell elements may be controlled by a plurality of word lines WL, Coded-GSL, DMY, and/or GSL. For example, the plurality of ground selection elements may be controlled by one or more ground selection lines Coded-GSL or by the common ground selection line GSL.

Specifically, each of the plurality of word lines WL, Coded-GSL, DMY, and GSL may extend in the second direction D2 and control the plurality of elements connected thereto. In some example embodiments, each of the plurality of word lines WL, Coded-GSL, DMY, and GSL may be connected in common to elements disposed at location levels corresponding to each other with respect to the upper surface of the substrate among the plurality of elements.

In some example embodiments, the location level may be a distance or a height with respect to the substrate in the third direction D3. For example, the elements disposed at a location level corresponding to each other with respect to the upper surface of the substrate may refer to elements disposed at an identical height to each other with respect to the upper surface of the substrate (i.e., in the third direction D3). Ground selection elements disposed at a location level corresponding to each other with respect to the upper surface of the substrate may refer to elements disposed at an identical height to each other with respect to the common source line CSL. In some example embodiments, a plurality of elements disposed at an identical height to each other with respect to the upper surface of the substrate or with respect to the common source line CSL may be connected in common to one of the plurality of word lines WL, Coded-GSL, DMY, or GSL. Specifically, the plurality of word lines may connect gate electrodes of elements disposed at an identical level with respect to the upper surface of the substrate or the common source line CSL among a plurality of elements included in the plurality of cell strings CS.

In some example embodiments, in each of the cell strings CS, threshold voltages of the plurality of ground selection elements may be coded. In some example embodiments, the threshold voltages of the plurality of ground selection elements being coded may represent that the threshold voltages of the plurality of ground selection elements are programmed in one of a high pattern or a low pattern.

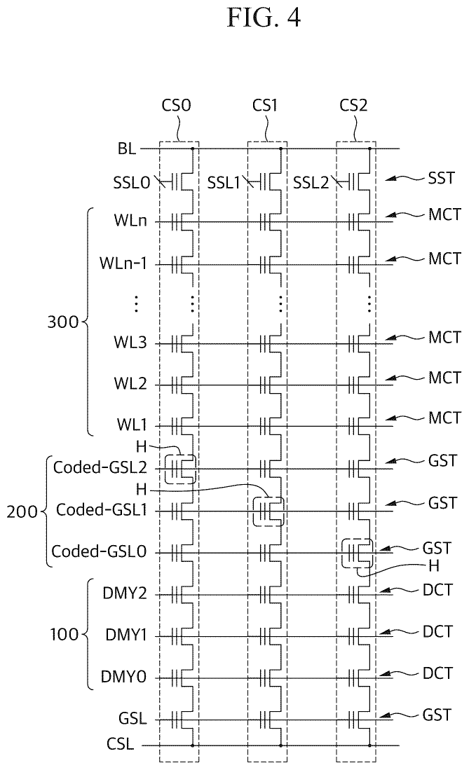

FIG. 4 is a circuit diagram illustrating a plurality of cell strings according to example embodiments.

Referring to FIG. 4, a plurality of cell strings CS0 to CS2 included in the memory cell array are illustrated.

In an example embodiment, the plurality of cell strings CS0 to CS2 may be connected in parallel between one bit line BL and the common source line CSL. A string selection element SST of each of the plurality of cell strings CS0 to CS2 may be controlled by corresponding string selection lines SSL0 to SSL2. For example, a string selection element SST of the cell string CS0 may be controlled by a corresponding string selection line SSL0, and a string selection element SST of the cell string CS1 may be controlled by a corresponding string selection line SSL1, etc.

Threshold voltages of a plurality of ground selection elements GST included in each of the plurality of cell strings CS0 to CS2 may be coded. According to an example embodiment, a plurality of string selection lines SSL0 to SSL2 may be connected to one common ground selection line GSL. For example, a ground selection element GST of each of the plurality of cell strings CS0 to CS2 may be connected to the common ground selection line GSL. In some example embodiments, to control a connection between the plurality of string selection lines SSL0 to SSL2 connected to the common ground selection line GSL and the common source line CSL, the memory cell array may include one or more ground selection lines Coded-GSL0 to Coded-GSL2 different from the common ground selection line GSL, and in some example embodiments, a threshold voltage may be coded on the one or more ground selection lines Coded-GSL0 to Coded-GSL2. The threshold voltage may be predetermined.

The ground selection elements GST indicated as “H” in FIG. 4 represent the ground selection elements GST whose threshold voltages are coded in the high pattern. As an example, threshold voltages may be coded in the high pattern, of the ground selection element GST connected to a third ground selection line Coded-GSL2 in a first cell string CS0, the ground selection element GST connected to a second ground selection line Coded-GSL1 in a second cell string CS1, and the ground selection element GST connected to a first ground selection line Coded-GSL0 in a third cell string CS2. Threshold voltages may be coded in the low pattern, of the ground selection elements GST not having the high pattern as the threshold voltages in the first to third cell strings CS0 to CS2.

As illustrated above, when the high pattern or the low pattern is coded on the plurality of ground selection elements GST of a plurality of ground selection lines Coded-GSL0 to Coded-GSL2, the connection to the common source line CSL may be controlled by applying different operating voltages to first to third source selection lines SSL0 to SSL2.

The ground selection element GST connected to the third ground selection line Coded-GSL2 in the first cell string CS0 may be turned on by an operating voltage greater than the high pattern, and the ground selection elements GST connected to the second ground selection line Coded-GSL1 and the first ground selection line Coded-GSL0 may be turned on by an operating voltage greater than the low pattern and less than the high pattern.

Similarly, the ground selection element GST connected to the second ground selection line Coded-GSL1 in the second cell string CS1 may be turned on by an operating voltage greater than the high pattern, and the ground selection elements GST connected to the third ground selection line Coded-GSL2 and the first ground selection line Coded-GSL0 may be turned on by an operating voltage greater than the low pattern and less than the high pattern.

The ground selection element GST connected to the first ground selection line Coded-GSL0 in the third cell string CS2 may be turned on by an operating voltage greater than the high pattern, and the ground selection elements GST connected to the second ground selection line Coded-GSL1 and the third ground selection line Coded-GSL0 may be turned on by an operating voltage greater than the low pattern and less than the high pattern.

As an example, based on locations of the plurality of ground selection lines Coded-GSL0 to Coded-GSL2, an electrical connection to the bit line BL or the common source line CSL of the ground selection elements GST of the first to third cell strings CS0 to CS2 connected to the third ground selection line Coded-GSL2 may be controlled according to an operating voltage applied to the third ground selection line Coded-GSL2. This operating voltage is similarly applied to the second ground selection line Coded-GSL1 and the first ground selection line Coded-GSL0, and since a manner of controlling the connection to the common source line CSL using the coded ground selection line Coded-GSL will apparent to those of ordinary skill in the art, further detailed description is omitted for conciseness.

FIG. 4 is merely an example embodiment for convenience of description, and the number and structures of the plurality of cell strings CS0 to CS2, the plurality of word lines SSL0 to SSL2, WL1 to WLn, Coded-GSL0 to Coded-GSL2, DMY0 to DMY2, GSL, and CSL, and a plurality of elements SST, MCT, GST, and DCT of FIG. 4 are not limited to those illustrated.

In FIGS. 3 and 4, a region that includes one or more dummy word lines is referred to as a dummy cell region 100, a region that includes one or more ground selection lines Coded-GSL and controls the connection between the common source line CSL and the plurality of string selection lines SSL is referred to as a first cell region 200, and a region that includes a plurality of main word lines and stores data is referred to as a second cell region 300.

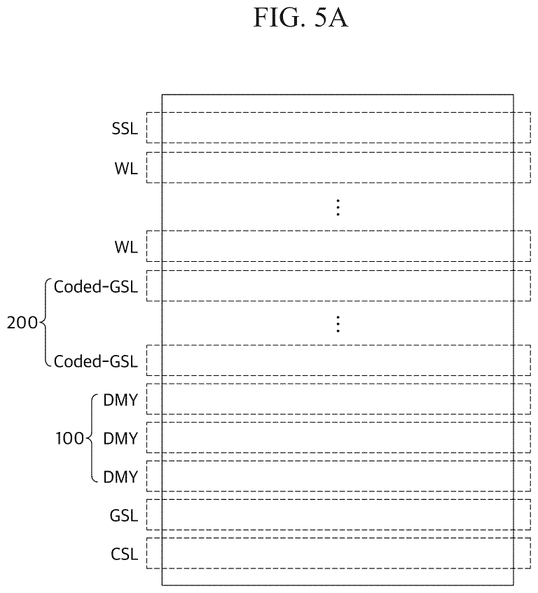

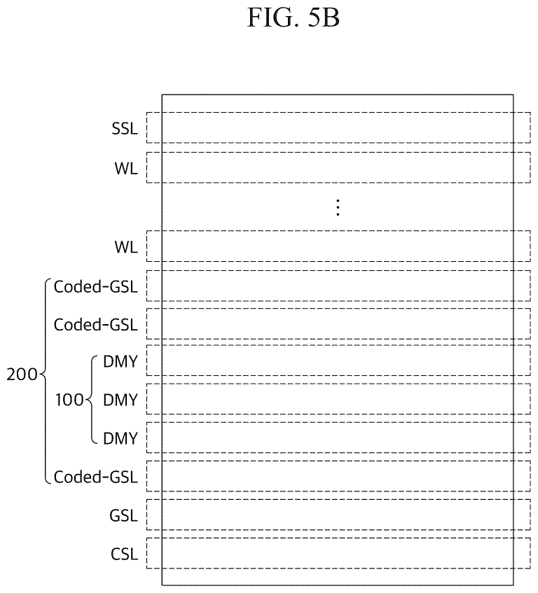

FIGS. 5A and 5B are plan views showing a memory device according to example embodiments.

According to an example embodiment, the dummy cell region 100 including one or more dummy word lines DMY may be disposed in the first cell region 200 or between the common source line CSL and the first cell region 200. As an example, referring to FIG. 5A, the dummy cell region 100 may be disposed between the common source line CSL and the first cell region 200.

As illustrated above, as one of a high pattern and a low pattern is coded on a plurality of ground selection elements of the first cell region, each of the plurality of ground selection elements may have a determined threshold voltage, and as the threshold voltage is coded as determined, the data reliability of the memory device is ensured. However, a high voltage may be applied to a word line during an operation such as a program operation for the memory device, and accordingly, data in an adjacent element may be damaged, changing some of threshold voltages coded on the plurality of ground selection elements in a coding process. Therefore, to prevent this damage and changing of some of the threshold voltages, when coding a pattern (in particular, the high pattern) on an element, the remaining elements connected to an identical word line or an identical ground selection line may be deactivated to inhibit an influence thereon through the string selection line SSL and the common ground selection line GSL corresponding thereto.

For example, when a program voltage is applied to code a lowermost ground selection line Coded-GSL and the common ground selection line GSL is grounded, if the dummy word line DMY is not present, a sharp potential difference between the lowermost ground selection line Coded-GSL and the common ground selection line GSL may lead to transition disturbance or the like, which may make it difficult to inhibit interference with the remaining elements. Therefore, to protect elements other than a target element for coding, one or more dummy word lines DMY may be provided between one or more ground selection lines Coded-GSL and the common ground selection line GSL to form a gradual potential change. For example, since the dummy cell region 100 is disposed between the common source line and the first cell region 200, the coding reliability for the first cell region 200 may be enhanced.

According to some example embodiments, the dummy cell region 100 including one or more dummy word lines DMY may be disposed in the first cell region 200 as in FIG. 5B. The dummy cell region 100 being disposed in the first cell region 200 may represent that the dummy cell region 100 is included in the first cell region 200. In other words, the one or more dummy word lines DMY may have one or more ground selection lines Coded-GSL above and below the one or more dummy word lines DMY, as illustrated in the example of FIG. 5B in which two ground selection lines Coded-GSL are provided above the dummy word lines DMY and one ground selection line Coded-GSL is provided below the dummy word lines DMY.

When the first cell region 200 includes three ground selection lines Coded-GSL but a difference between voltages, which are applied to gates during coding, of a lowermost ground selection line Coded-GSL and a middle ground selection line Coded-GSL is large, a potential difference may gradually decrease as the dummy word line DMY is disposed between the two ground selection lines Coded-GSL.

In some example embodiments, some of a plurality of dummy word lines DMY may be disposed in the first cell region 200, and the others of the plurality of dummy word lines DMY may be disposed between the first cell region 200 and the common ground selection line GSL. In other words, since the dummy word line DMY is disposed between any two word lines with a sharp change of a potential difference, a gradual potential difference may be formed.

The number and arrangement of a plurality of word lines CSL, GSL, DMY, Coded-GSL, and WL illustrated in FIGS. 5A and 5B are only examples and embodiments are not limited to those illustrated.

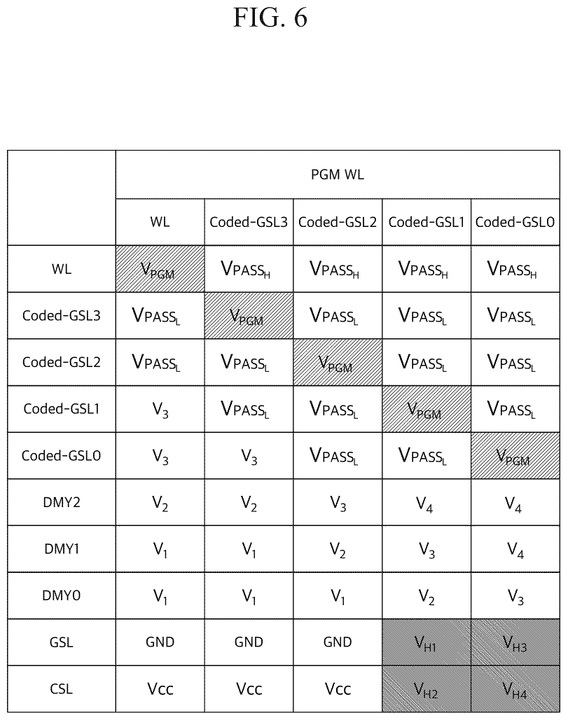

FIG. 6 is a diagram for illustrating a method of applying a voltage to a memory device according to example embodiments.

In a table illustrated in FIG. 6, a target word line to which a program voltage is applied for coding is indicated in a row, and voltages applied to each of a plurality of word lines are indicated in a column. In some example embodiments, the plurality of word lines may include a plurality of main word lines WL, one or more ground selection lines Coded-GSL, and one or more dummy word lines DMY. In the following description including a description of FIG. 6, V_{PGM}, V_{PASS}_{_{H}}, V_{PASS}_{_{L}}, V₄, V₃, V₂, V₁, V_{H4}, V_{H3}, V_{H2}, and V_{H1} may be arranged in order from the largest voltage to the smallest voltage.

According to an example embodiment, a voltage of a size determined based on a location level with respect to a substrate may be applied to the plurality of word lines. As an example, when a program voltage V_{PGM} is applied to one target word line among the plurality of word lines, a voltage less than the program voltage V_{PGM} may be applied to a plurality of word lines disposed at a lower level than the target word line.

For example, when the target word line is the main word line WL, voltages V_{PASS}_{_{L}}, V₃, V₂, V₁, and GND that are less than the program voltage V_{PGM} may be applied to a plurality of word lines Coded-GSL0 to Coded-GSL3, DMY0 to DMY2, and GSL disposed at lower levels than the main word line WL. In some example embodiments, GND may be 0 volt (V) as a ground voltage. When the target word line is a fourth ground selection line Coded-GSL3, voltages V_{PASS}_{_{L}}, V₃, V₂, V₁, and GND that are less than the program voltage V_{PGM} may be applied to a plurality of word lines Coded-GSL0 to Coded-GSL2, DMY0 to DMY2, and GSL disposed at lower levels than the fourth ground selection line Coded-GSL3. When the target word line is the third ground selection line Coded-GSL2, voltages V_{PASS}_{_{L}}, V₃, V₂, V₁, and GND that are less than the program voltage V_{PGM} may be applied to a plurality of word lines Coded-GSL0 and Coded-GSL1, DMY0 to DMY2, and GSL disposed at lower levels than the third ground selection line Coded-GSL2. When the target word line is the second ground selection line Coded-GSL1, voltages V_{PASS}_{_{L}}, V₄, V₃, V₂, and V_{H1} that are less than the program voltage V_{PGM} may be applied to a plurality of word lines Coded-GSL0, DMY0 to DMY2, and GSL disposed at lower levels than the second ground selection line Coded-GSL1. When the target word line is the first ground selection line Coded-GSL0, voltages V₄, V₃, and V_{H3} that are less than the program voltage V_{PGM} may be applied to a plurality of word lines DMY0 to DMY2 and GSL disposed at lower levels than the first ground selection line Coded-GSL0.

According to an example embodiment, when the program voltage is applied to the target word line, a voltage of a lesser or equal size may be applied, as the location level is lower, to each of the plurality of word lines disposed at the lower level than the target word line.

For example, when the target word line is the main word line WL, a voltage V_{PASS}_{_{L}} that is less than the program voltage V_{PGM} may be applied to the fourth ground selection line Coded-GSL3 disposed at a lower level than the main word line WL, and a voltage V_{PASS}_{_{L}} equal to the voltage V_{PASS}_{_{L}} applied to the fourth ground selection line Coded-GSL3 may be applied to the third ground selection line Coded-GSL2 disposed at a lower level than the fourth ground selection line Coded-GSL3. A voltage of a lesser or equal size may be applied, as a location level is lower, identically to word lines disposed at a lower location level than the third ground selection line Coded-GSL2. Referring to FIG. 6, it may be identified that these example embodiments are applied identically to when the target word line is the ground selection lines Coded-GSL0 to Coded-GSL3 other than the main word line WL.

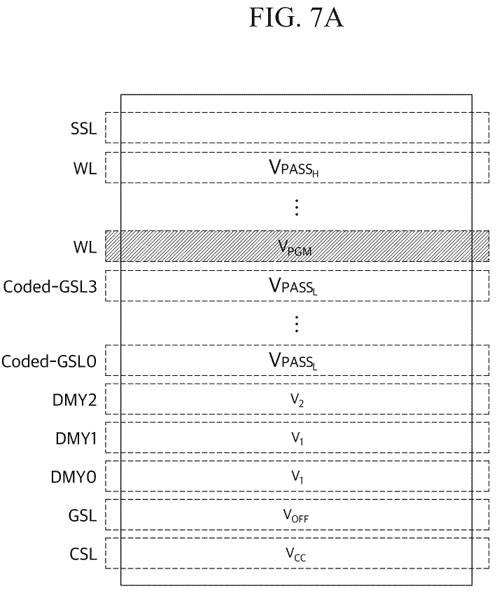

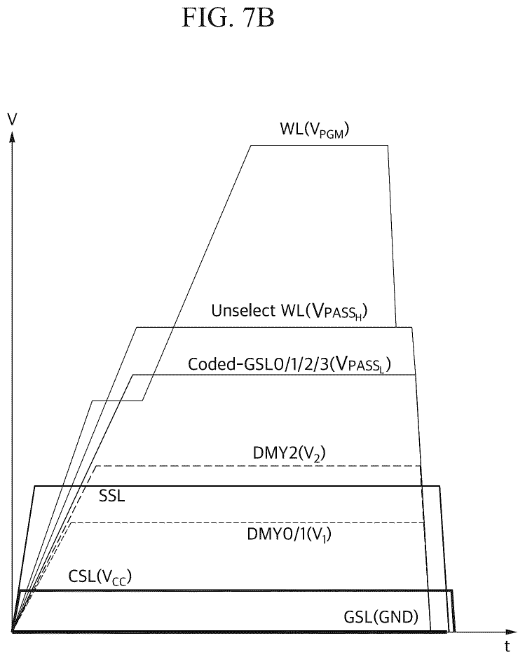

FIGS. 7A, 7B, 8A, 8B, 9A, and 9B are diagrams for illustrating a method of applying a voltage to a memory device according to example embodiments.

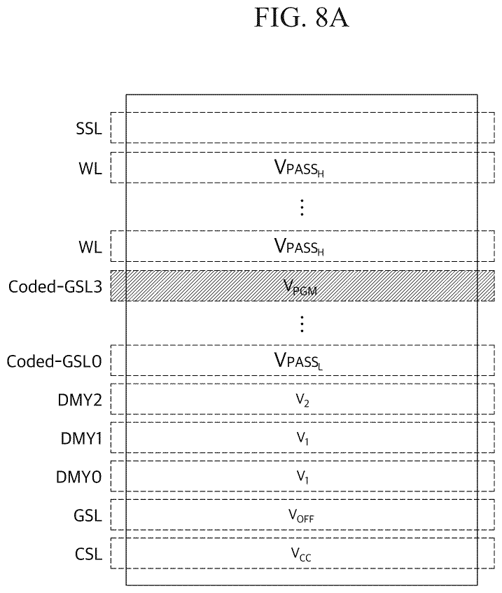

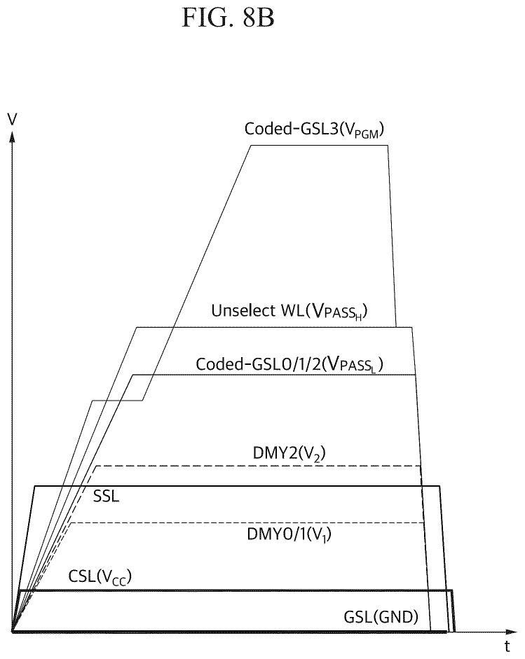

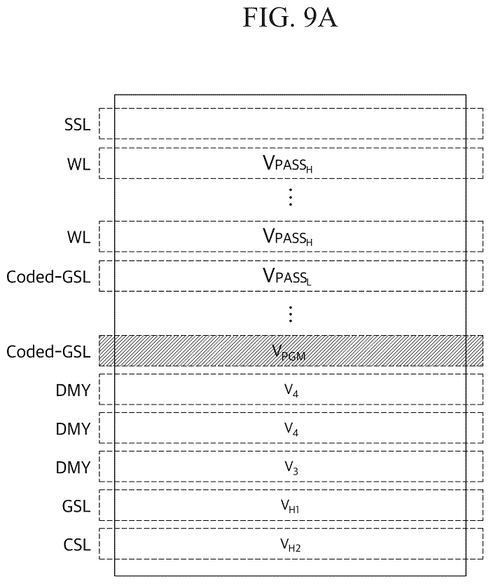

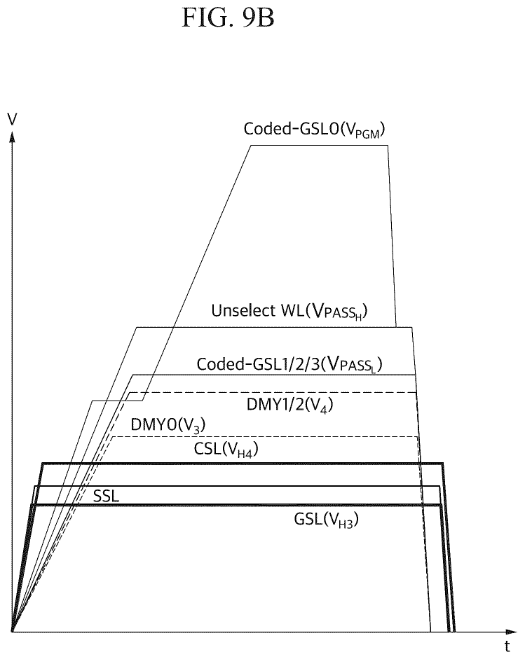

FIGS. 7A and 7B are diagrams for illustrating the method of applying the voltage to the memory device when a program voltage is applied to the second cell region of a selected word line, and FIGS. 8A to 9B are diagrams for illustrating the method of applying the voltage to the memory device when a program voltage is applied to the first cell region.

Referring to FIGS. 7A and 7B, an example embodiment is illustrated, in which a target word line is the main word line WL as in the first column of FIG. 6.

According to an example embodiment, when the program voltage V_{PGM} is applied to a selected word line of the plurality of main word lines WL, a first set voltage V_{PASS}_{_{H}} that is less than the program voltage may be applied to an unselected word line Unselect-WL among the plurality of main word lines WL.

A set voltage of a size that is less than or equal to the first set voltage V_{PASS}_{_{L}} may be applied to one or more ground selection lines. For example, referring to a graph of FIG. 7B, a set voltage V_{PASS}_{_{L}} of a size that is less than the first set voltage V_{PASS}_{_{H}} may be applied to a plurality of ground selection lines Coded-GSL0 to Coded-GSL3.

A set voltage of a size that is less than or equal to a minimum value of the set voltage V_{PASS}_{_{L}} applied to the one or more ground selection lines and greater than a source voltage V_{CC} applied to a common source line may be applied to one or more dummy word lines. For example, referring to the graph of FIG. 7B, set voltages V₂ and V₁ of a size that is less than the minimum value of the set voltage V_{PASS}_{_{L}} applied to the plurality of ground selection lines Coded-GSL0 to Coded-GSL3 and greater than the source voltage V_{CC} applied to the common source line CSL may be applied to each of a plurality of dummy word lines DMY0 to DMY2. In some example embodiments, according to example embodiments described above, a voltage of a lesser or equal size may be applied as the location level is lower.

An off voltage V_{OFF} of a size that is less than the source voltage V_{CC} may be applied to a common ground selection line.

Referring to FIGS. 8A and 8B, an example embodiment is illustrated, in which a target word line is the fourth ground selection line Coded-GSL3 as in the second column of FIG. 6.

According to an example embodiment, when the program voltage V_{PGM} is applied to one target word line of a plurality of ground selection lines, a first set voltage V_{PASS}_{_{H}} that is less than the program voltage V_{PGM} may be applied to a plurality of main word lines.

A set voltage of a size that is less than or equal to the first set voltage V_{PASS}_{_{H}} may be applied to an unselected ground selection line excluding the target word line from the plurality of ground selection lines. For example, referring to a graph of FIG. 8B, a set voltage V_{PASS}_{_{L}} of a size that is less than the first set voltage V_{PASS}_{_{H}} may be applied to unselected ground selection lines Coded-GSL0 to Coded-GSL2 excluding the target word line Coded-GSL3 from the plurality of ground selection lines Coded-GSL0 to Coded-GSL3.

A set voltage of a size that is less than or equal to a minimum value of the voltage V_{PASS}_{_{L}} applied to the unselected ground selection line and greater than a source voltage applied to a common source line may be applied to one or more dummy word lines. For example, referring to the graph of FIG. 8B, set voltages V₂ and V₁ of a size that is less than the minimum value of the voltage V_{PASS}_{_{L}} applied to the unselected ground selection lines Coded-GSL0 to Coded-GSL2 and greater than the source voltage V_{CC} applied to the common source line CSL may be applied to the plurality of dummy word lines DMY0 to DMY2.

The off voltage V_{OFF} of a size that is less than the source voltage V_{CC} may be applied to a common ground selection line.

Referring to FIGS. 9A and 9B, an example embodiment is illustrated, in which a target word line is the first ground selection line Coded-GSL0 as in the fifth column of FIG. 6.

As described through FIGS. 8A and 8B, when a program voltage is applied to one target word line among a plurality of ground selection lines, a first set voltage lesser than the program voltage may be applied to a plurality of main word lines, and a set voltage of a size that is less than or equal to the first set voltage may be applied to an unselected ground selection line excluding the target word line from the plurality of ground selection lines, and a set voltage of a size that is less than or equal to a minimum value of the voltage applied to the unselected ground selection line and greater than a source voltage applied to a common source line may be applied to one or more dummy word lines, and an off voltage of a size that is less than the source voltage may be applied to a common ground selection line.

Referring to FIGS. 8A and 9B, according to an example embodiment, sizes of voltages applied to a plurality of word lines may be determined based on a location level of a target word line. When the location level of the target word line with respect to an upper surface of a substrate is low, a gap with the common ground selection line GSL to which the off voltage V_{OFF} is applied is narrow, and thus, a size of a voltage applied to the plurality of dummy word lines DMY may be relatively greater, compared to when the location level of the target word line with respect to the upper surface of the substrate is high. This difference in voltage application is because a difference between the program voltage V_{PGM} and the off voltage V_{OFF} is mitigated using a smaller number of dummy word lines DMY.

According to an example embodiment, the off voltage V_{OFF} applied to the common ground selection line GSL may be determined based on a location level of a target word line. When the location level of the target word line with respect to an upper surface of a substrate is low, a gap with the common ground selection line GSL to which the off voltage V_{OFF} is applied is narrow, and thus, the off voltage V_{OFF} applied to the common ground selection line GSL may be increased to reduce a difference between the program voltage V_{PGM} and the off voltage V_{OFF}. In some example embodiments, the source voltage V_{CC} applied to the common source line CSL may also be increased together (for example, when V_{OFF} is V_{H1}, to V_{H2}, or when V_{OFF} is V_{H3}, ¿V_{H4}), and the off voltage V_{OFF} may have a voltage value lesser than the source voltage V_{CC} by a reference value. The reference value may be predetermined.

Referring to FIGS. 7B, 8B, and 9B, according to an example embodiment, a voltage may be applied to a plurality of word lines during a setup period of each of the plurality of word lines, and the setup period may be set to end at an earlier time point from an identical time point in descending order of a size of a voltage to be applied.

Specifically, the setup period may refer to a period from a time point at which a voltage size starts to increase to a time point at which the voltage size starts to decrease in a graph as illustrated by way of example in FIGS. 7B, 8B, and 9B. In some example embodiments, even when voltages are applied starting from an identical time point, it may be identified that a setup period becomes shorter as a size of a voltage to be applied becomes greater. For example, as illustrated in FIG. 7B, the voltages V_{PGM}, V_{PASS}_{_{H}}, V_{PASS}_{_{L}}, V₂, V₁, V_{cc}, and GND are applied starting from time point t=0, and the setup period from the time point at which the voltage size starts to increase (e.g., t=0) to the time point at which the voltage size starts to decrease becomes shorter as the size of the voltage to be applied becomes greater. Thus, for example, the setup period “setup period VPGM” of V_{PGM}, which has a greater size than V_{PASS}_{_{H}} is shorter than the setup period “setup period VPASSH” of V_{PAS}_{_{S}}H. Similarly, the setup period “setup period V2” of V₂, which has a greater size than V₁ is shorter than the setup period “setup period V1” of V₁.

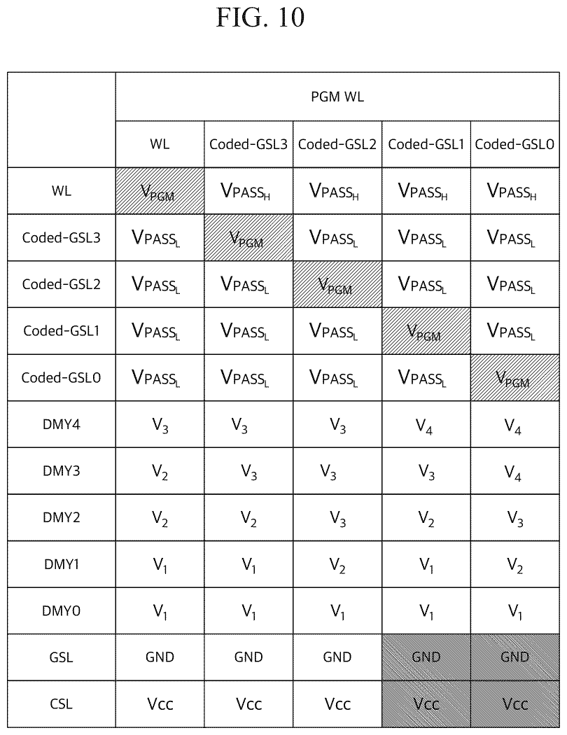

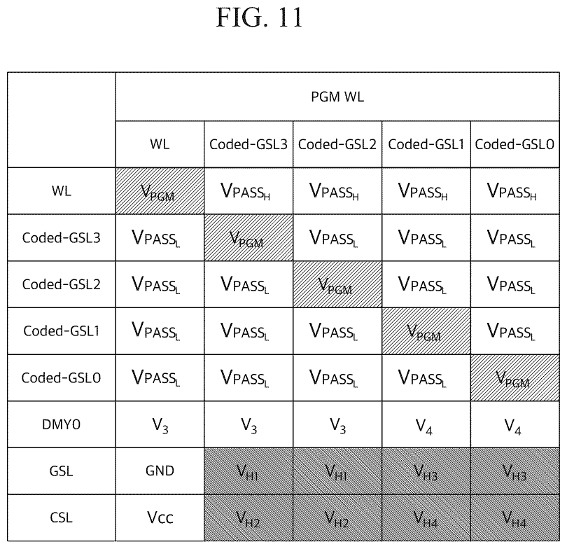

FIGS. 10 and 11 are diagrams for illustrating a method of applying a voltage to a memory device according to example embodiments.

According to an example embodiment, a size of a voltage applied to a plurality of word lines WL, Coded-GSL, DMY, GSL, and CSL may be determined based on the number of one or more dummy word lines DMY.

The dummy word line DMY is a component for gradually decreasing a potential difference between the common ground selection line GSL to which the off voltage V_{OFF} is applied and a target word line to which the program voltage V_{PGM} is applied, and as the number of the dummy word lines DMY becomes greater, two adjacent dummy word lines DMY among a plurality of dummy word lines DMY may have voltages of an equal size with each other or with a small difference therebetween. In contrast, since the potential difference between the common ground selection line GSL and the target word line is to be sharply decreased as the number of the dummy word lines DMY is fewer, two adjacent dummy word lines DMY among the plurality of dummy word lines DMY may have voltages with a large difference with therebetween.

Referring to FIGS. 6 and 10 in comparison, in an example embodiment of FIG. 10 in which the number of the dummy word lines DMY is more, it may be identified that two adjacent dummy word lines DMY among the plurality of dummy word lines DMY have voltages of an equal size or with a small difference therebetween, compared to the example embodiments of FIG. 6 in which the number of the dummy word lines DMY is relatively few.

According to an example embodiment, the off voltage V_{OFF} applied to the common ground selection line GSL may be determined based on the number of one or more dummy word lines DMY.

The potential difference between the off voltage V_{OFF} the common ground selection line GSL and the program voltage V_{PGM} applied to the target word line is to be sharply decreased as the number of the dummy word lines DMY is fewer, and in some example embodiments, by increasing the off voltage V_{OFF} applied to the common ground selection line GSL, the difference between the program voltage V_{PGM} and the off voltage V_{OFF} may decrease. In some example embodiments, the source voltage V_{CC} applied to the common source line CSL may also be increased together, and the off voltage V_{OFF} may have a voltage value smaller than the source voltage V_{CC} by a predetermined value.

As an example, if the number of one or more dummy word lines DMY is greater than or equal to a threshold number, the off voltage V_{OFF} may be the ground voltage GND, and if the number of one or more dummy word lines DMY is less than the threshold number, when the program voltage is applied to a word line among a plurality of word lines, the off voltage V_{OFF} may be a voltage higher than the ground voltage GND and lower than a voltage applied to the common source line CSL. For example, assuming that the threshold number is 2, referring to FIG. 11, an example embodiment with a number of dummy word lines DMY is less than the threshold number is illustrated, i.e., only one dummy word line DMY0. In some example embodiments, the off voltage V_{OFF} applied to the common ground selection line GSL may be a voltage V_{H1} or V_{H3} higher than the ground voltage GND when the program voltage is applied to the ground selection lines Coded-GSL0 to Coded-GSL3 among a plurality of word lines WL, Coded-GSL0 to Coded-GSL3, DMY0, and GSL. However, this is merely an example embodiment, and the threshold number of the dummy word lines DMY and the form of the word line to which the program voltage is applied are not limited to the example embodiments in FIGS. 10 and 11 and may be implemented in various ways.

V_{H2} or V_{H4}, an example of the source voltage V_{OFF} applied to the common source line CSL, may be a voltage value of a size corresponding to a range of 3 V to 6 V or a range of 6 V to 9 V, respectively, and V_{H1} and V_{H3} described above as examples of the off voltage V_{OFF} applied to the common ground selection line GSL may be voltage values of a size that is less than that by a reference value (for example, 1 to 2 V).

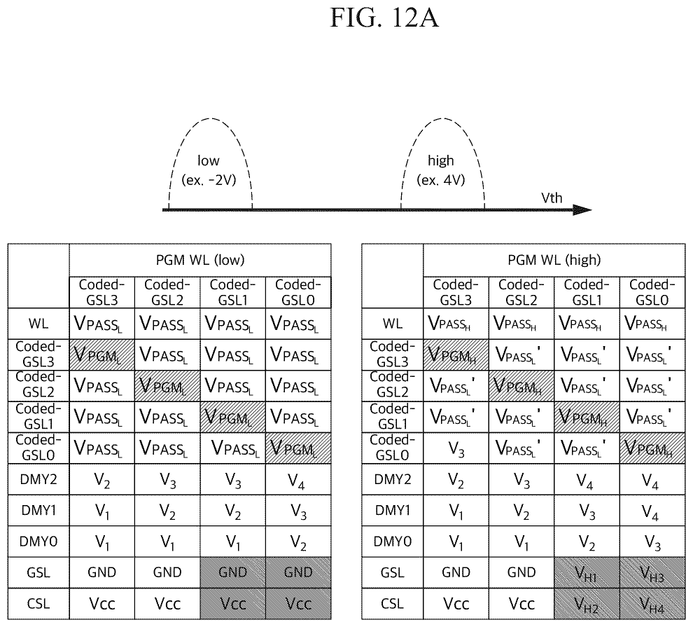

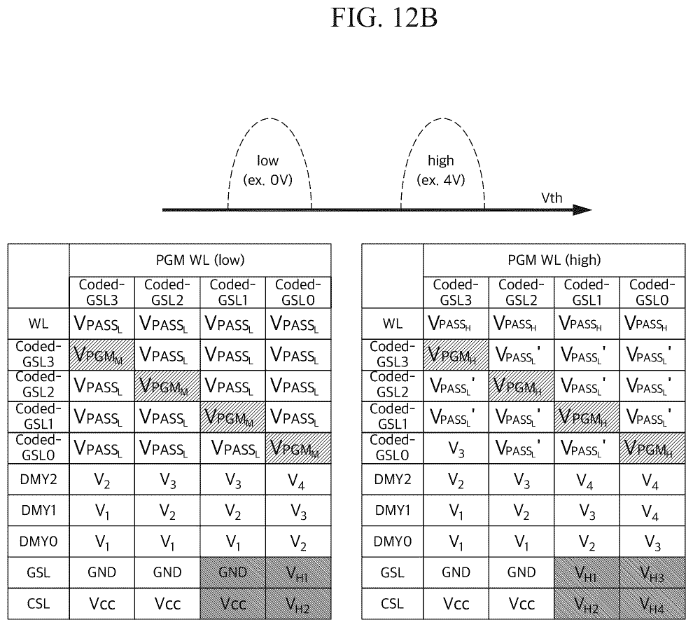

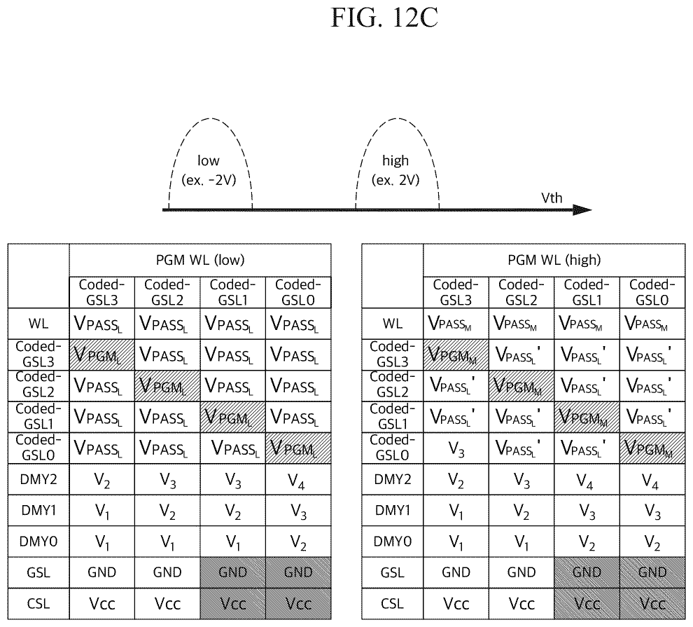

FIGS. 12A to 12C are diagrams for illustrating a method of applying a voltage to a memory device based on a threshold voltage according to example embodiments.

In FIGS. 12A to 12C, the method of applying the voltage to the memory device is illustrated, when the program voltage V_{PGM} is applied to code a threshold voltage of the low pattern and when the program voltage V_{PGM} is applied to code a threshold voltage of the high pattern. In the example embodiments, V_{PASS}_{_{L}}′ is a value greater than or equal to V_{PASS}_{_{L}} and less than V_{PASS}_{_{M}}.

According to an example embodiment, a size of a voltage applied to a plurality of word lines WL, Coded-GSL, DMY, GSL, and CSL may be determined based on a size of the program voltage V_{PGM}. Referring to FIGS. 12A and 12B (a size of the low pattern is −2 V and 0 V, respectively) in comparison, a program voltage V_{PGM}_{_{L}} of a relatively small size may be applied to a target word line as the size of the low pattern becomes smaller. In some example embodiments, when the program voltage V_{PGM}_{_{L}} is small, a potential difference from the off voltage V_{OFF} applied to the common ground selection line GSL may be relatively small, and thus, the size of the voltage applied to the plurality of word lines WL, Coded-GSL, DMY, GSL, and CSL may be different, compared to when a program voltage V_{PGM}_{_{M}} of a relatively large size is applied.

Similarly, referring to FIGS. 12A and 12C (a size of the high pattern is 4 V and 2 V, respectively) in comparison, the program voltage VPGMM of a relatively small size may be applied to a target word line as the size of the high pattern becomes less. In some example embodiments, when the program voltage V_{PGM}_{_{M}} is small, a potential difference from the off voltage V_{OFF} applied to the common ground selection line GSL may be relatively small, and thus, the size of the voltage applied to the plurality of word lines WL, Coded-GSL, DMY, GSL, and CSL may be different, compared to when a program voltage V_{PGM}_{_{H}} of a relatively large size is applied. Referring to FIG. 12C, a voltage V_{PASS}_{_{L}}′ applied to a plurality of ground selection lines Coded-GSL0 to Coded-GSL3 may be greater than or equal to a voltage V_{PASS}_{_{L}} of FIG. 12A.

According to an example embodiment, a size of the off voltage V_{OFF} applied to the common ground selection line GSL may be determined based on a size of the program voltage V_{PGM}. Referring to FIGS. 12B and 12C in comparison, it may be identified that the off voltage V_{OFF} is determined as a voltage other than the ground voltage GND to decrease a potential difference between the program voltage V_{PGM} and the off voltage V_{OFF} when both the low pattern and the high pattern have higher threshold voltages (in an example embodiment of FIG. 12B). Specifically, the off voltage V_{OFF} may be determined as V_{H1} when the program voltage V_{PGM}_{_{H}} is applied to code the high pattern (4 V) on the second ground selection line Coded-GSL1, and the off voltage V_{OFF} may be determined as V_{H3} when the program voltage V_{PGM}_{_{H}} is applied to code the high pattern (4 V) on the first ground selection line Coded-GSL0. In contrast, the off voltage V_{OFF} may be determined as the ground voltage GND when the program voltage V_{PGM}_{_{M}} is applied to code the low pattern (2 V) on the second ground selection line Coded-GSL1.

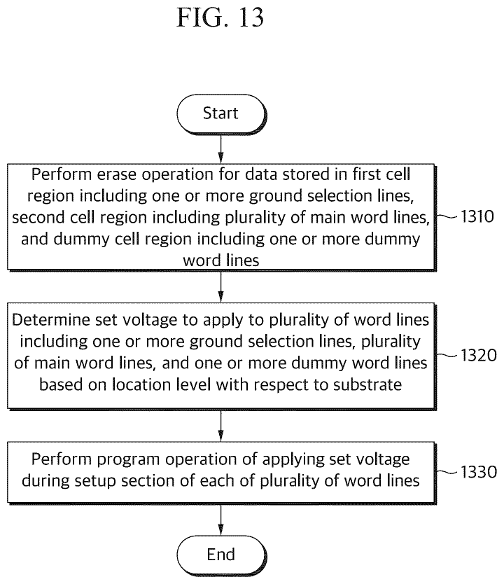

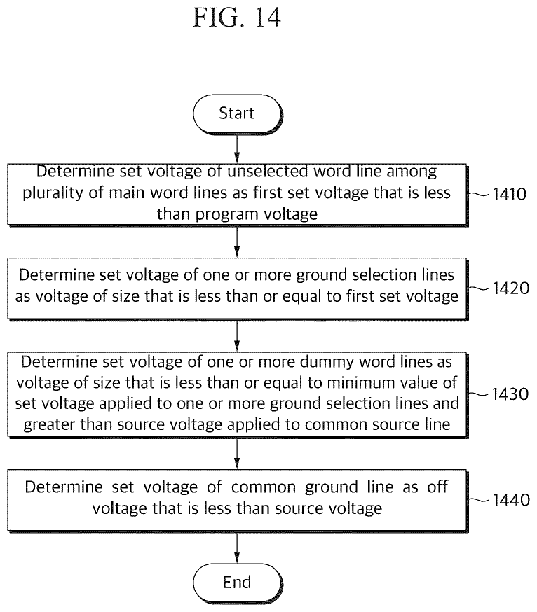

FIGS. 13 and 14 are flowcharts of a method of operation of a memory device according to example embodiments.

Each operation of FIGS. 13 and 14 may be performed by a device (hereinafter referred to as the “device”) such as a peripheral circuit (for example, a control logic) or an external device (for example, a server). Specifically, each operation of FIGS. 13 and 14 may be performed by a processor included in the device.

Referring to FIG. 13, in operation 1310, the device may perform an erase operation for data stored in a first cell region including one or more ground selection lines, a second cell region including a plurality of main word lines, and a dummy cell region including one or more dummy word lines. This erase operation may correspond to an operation of erasing existing data before coding for the first cell region and the second cell region.

According to an example embodiment, the one or more ground selection lines may have dispersion of coded threshold voltages.

According to an example embodiment, the first cell region may be disposed between a common source line and the second cell region.

According to an example embodiment, a dummy cell region may be disposed in the first cell region or between the common source line and the first cell region.

According to an example embodiment, a plurality of word lines may further include a common ground line.

In operation 1320, the device may determine a set voltage to apply to the plurality of word lines including the one or more ground selection lines, the plurality of main word lines, and the one or more dummy word lines based on a location level with respect to a substrate.

According to an example embodiment, the device may determine, in response to determining the set voltage of one target word line among the plurality of word lines as a program voltage, the set voltage of a plurality of word lines disposed at a lower level than the target word line as a voltage that is less than the program voltage.

According to an example embodiment, the device may determine the set voltage of each of the plurality of word lines disposed at the lower level than the target word line as a voltage of a lesser size or equal size as the location level becomes lower.

According to an example embodiment, the device may determine the set voltage based on at least one of a number of the one or more dummy word lines, a size of the program voltage, or a location level of the target word line.

According to an example embodiment, the device may determine the set voltage of the common ground line based on at least one of the number of the one or more dummy word lines, the size of the program voltage, or the location level of the target word line.

According to an example embodiment, the set voltage of the common ground line may be, if the number of the one or more dummy word lines is greater than or equal to a threshold number, a ground voltage, and if the number of the one or more dummy word lines is less than the threshold number, when the program voltage is applied to a word line among the plurality of word lines, a voltage higher than the ground voltage and lower than a voltage applied to the common source line.

In operation 1330, the device may perform a program operation of applying the set voltage during a setup period of each of the plurality of word lines.

According to an example embodiment, the setup period of each of the plurality of word lines may be set to end at an earlier time point from an identical time point in descending order of the set voltage.

Referring to FIG. 14, when a program voltage is applied to a selected word line among the plurality of main word lines by the device, a flowchart of a method of determining set voltages of other word lines is illustrated.

In operation 1410, the device may determine the set voltage of an unselected word line among the plurality of main word lines as a first set voltage that is less than the program voltage.

In operation 1420, the device may determine the set voltage of the one or more ground selection lines as a voltage of a size that is less than or equal to the first set voltage.

In operation 1430, the device may determine the set voltage of the one or more dummy word lines as a voltage of a size that is less than or equal to a minimum value of the set voltage applied to the one or more ground selection lines and greater than a source voltage applied to the common source line.

In operation 1440, the device may determine the set voltage of a common ground line as an off voltage that is less than the source voltage.

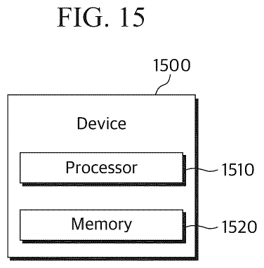

FIG. 15 is a block diagram of a device according to example embodiments.

Referring to FIG. 15, a device 1500 may include a processor 1510 and a memory 1520. In the device 1500 of FIG. 15, components related to example embodiments are only illustrated. Therefore, it may be understood by those of ordinary skill in the art that other general-purpose components may be further included in addition to the components illustrated in FIG. 15. In addition, as described above, the device 1500 may be a memory device or one component included in the memory device, or the device 1500 may also be a separate component outside the memory device.

FIG. 15 illustrates the single processor 1510, but the device 1500 may include any number of processors, and each processor may be a single-core processor or a multi-core processor, and each processor may implement a reduced instruction set computer (RISC) architecture or a complex instruction set computer (CISC) architecture (among other possibilities) and be mixed in a desired combination.

The memory 1520 is hardware for storing a variety of data processed within the device 1500 and may store programs for the processing and controlling of the processor 1510.

The memory 1520 may include random access memory (RAM), such as dynamic random access memory (DRAM) and static random access memory (SRAM), read-only memory (ROM), electrically erasable programmable read-only memory (EEPROM), CD-ROM, Blu-ray or other optical disk storage, hard disk drive (HDD), solid-state drive (SSD), or flash memory.

The processor 1510 may control overall operations of the device 1500. For example, the processor 1510 may overall control an input part (not shown), a display (not shown), a communication part (not shown), the memory 1520, and the like by executing the programs stored in the memory 1520. The processor 1510 may control the operation of the device 1500 by executing the programs stored in the memory 1520.

The processor 1510 may control at least some of the operations of the device described above in FIGS. 1 to 14.

The processor 1510 may be implemented using at least one of application specific integrated circuits (ASICs), digital signal processors (DSPs), digital signal processing devices (DSPDs), programmable logic devices (PLDs), field programmable gate arrays (FPGAs), controllers, micro-controllers, microprocessors, or electrical units for performing other functions.

According to an example embodiment, the device 1500 may be a server. The server may be implemented as a computer device or a plurality of computer devices providing instructions, codes, files, content, services, and the like by communicating through networks.

The device 1500 may further include a communication part (not shown). The communication part (not shown) may include one or more components that allow wired/wireless communications with an external server or an external device. For example, the communication part (not shown) may include at least one of a short-range communication part (not shown), a mobile communication part (not shown), and a broadcast reception part (not shown).

The electronic device according to the above-described example embodiments may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. Here, the computer-readable recording medium includes a magnetic storage medium (for example, read-only memory (ROM), random-access memory (RAM), floppy disks, and hard disks) and/or an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

The example embodiments may be represented by functional block elements and various processing operations. The functional blocks may be implemented in any number of hardware and/or software configurations that perform specific functions. For example, an example embodiment may adopt integrated circuit configurations, such as memory, processing, logic, and/or look-up table, which may execute various functions by the control of one or more microprocessors or other control devices. Similar to that elements may be implemented as software programming or software elements, the example embodiments may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means,” and “configuration” may be used broadly and are not limited to mechanical and physical configurations. The terms may include the meaning of a series of routines of software in association with a processor or the like.

The above-described example embodiments are merely examples, and other example embodiments and modifications thereof may be implemented within the scope of the appended claims.

What is claimed is:

1. A memory device comprising:
a common source line;
a first cell region configured to control a connection between the common source line and a plurality of string selection lines; and
a dummy cell region including one or more dummy word lines to which a plurality of dummy elements are connected,
wherein the dummy cell region is disposed in the first cell region or between the common source line and the first cell region.

2. The memory device of claim 1, wherein the memory device comprises a second cell region including a plurality of main word lines in which data is stored, and
wherein the first cell region includes one or more ground selection lines having a dispersion of coded threshold voltages, the first cell region being disposed between the common source line and the second cell region.

3. The memory device of claim 2, wherein a voltage of a size determined based on a location level of each of a plurality of word lines including the plurality of main word lines, the one or more ground selection lines, and the one or more dummy word lines with respect to a substrate on which the plurality of word lines are disposed is applied to each of the plurality of word lines.

4. The memory device of claim 3, wherein, when a program voltage is applied to a target word line among the plurality of word lines, a lesser voltage that is less than the program voltage is applied to word lines disposed at a lower level than a level of the target word line.

5. The memory device of claim 4, wherein, as the location level of the plurality of word lines disposed at the lower level than the target word line becomes lower, a voltage of a lesser or equal size to the lesser voltage is applied.

6. The memory device of claim 4, wherein the size of the lesser voltage is determined based on at least one of a number of the one or more dummy word lines, a size of the program voltage, or a location level of the target word line.

7. The memory device of claim 6, further comprising a common ground selection line to which an off voltage determined based on at least one of the number of the one or more dummy word lines, the size of the program voltage, and the location level of the target word line is applied.

8. The memory device of claim 7, wherein, if the number of the one or more dummy word lines is greater than or equal to a threshold number, the off voltage is a ground voltage, and
wherein, if the number of the one or more dummy word lines is less than the threshold number, when the program voltage is applied to a word line among the plurality of word lines, the off voltage is a voltage higher than the ground voltage and less than a voltage applied to the common source line.

9. The memory device of claim 5, wherein the voltage is applied during a setup period of each of the plurality of word lines, and
wherein the setup period is set to end at an earlier time point in descending order of the size of the voltage applied to each of the plurality of word lines.

10. The memory device of claim 1, wherein the dummy cell region is disposed between the common source line and the first cell region.

11. The memory device of claim 7, wherein, when a program voltage is applied to a selected word line among the plurality of main word lines,
a first set voltage less than the program voltage is applied to an unselected word line among the plurality of main word lines,
a second set voltage of a size less than or equal to the first set voltage is applied to the one or more ground selection lines,
a third set voltage of a size less than or equal to a minimum value of the second set voltage and greater than a source voltage applied to the common source line is applied to the one or more dummy word lines, and
the off voltage of a size less than the source voltage is applied to the common ground selection line.

12. The memory device of claim 7, wherein, when a program voltage is applied to a ground select target word line among a plurality of ground selection lines,
a first set voltage less than the program voltage is applied to the plurality of main word lines,
a second set voltage of a size less than or equal to the first set voltage is applied to an unselected ground selection line excluding the ground select target word line from among the plurality of ground selection lines,
a third set voltage of a size less than or equal to a minimum value of the second set voltage and greater than a source voltage applied to the common source line is applied to the one or more dummy word lines, and
the off voltage of a size less than the source voltage is applied to the common ground selection line.

13. A method of operation of a memory device, the method comprising:
performing an erase operation for data stored in a first cell region including one or more ground selection lines, a second cell region including a plurality of main word lines, and a dummy cell region including one or more dummy word lines;
determining a set voltage to apply to each of a plurality of word lines including the one or more ground selection lines, the plurality of main word lines, and the one or more dummy word lines based on a location level of the each of the plurality of word lines with respect to a substrate; and
performing a program operation of applying the set voltage during a setup period of each of the plurality of word lines,
wherein the dummy cell region is disposed in the first cell region or between a common source line and the first cell region.

14. The method of claim 13, wherein the determining includes, in response to determining the set voltage of a target word line among the plurality of word lines as a program voltage, determining the set voltage of word lines disposed at a lower location level than the location level the target word line as a lesser voltage that is less than the program voltage.

15. The method of claim 14, wherein determining the set voltage of the plurality of word lines disposed at the lower location level includes determining the set voltage of each of the plurality of word lines disposed at the lower location level than the target word line as a voltage of a lesser or equal size to the lesser voltage as the location level becomes lower.

16. The method of claim 14, wherein the set voltage is determined based on at least one of a number of the one or more dummy word lines, a size of the program voltage, and a location level of the target word line.

17. The method of claim 16, wherein the plurality of word lines further include a common ground line,
wherein determining the set voltage of the plurality of word lines disposed at the lower location level includes determining the set voltage of the common ground line based on at least one of the number of the one or more dummy word lines, the size of the program voltage, and the location level of the target word line, and
wherein the set voltage of the common ground line is:
if the number of the one or more dummy word lines is greater than or equal to a threshold number, a ground voltage, and
if the number of the one or more dummy word lines is less than the threshold number, when the program voltage is applied to a word line among the plurality of word lines, a voltage higher than the ground voltage and lower than a voltage applied to the common source line.

18. The method of claim 14, wherein the setup period of each of the plurality of word lines is set to end at an earlier time point from an identical time point in descending order of the size of the voltage applied to each of the plurality of the word lines.

19. The method of claim 13, wherein the determining includes:
when a program voltage is applied to a selected word line among the plurality of main word lines,
determining the set voltage of an unselected word line among the plurality of main word lines as a first set voltage less than the program voltage;
determining the set voltage of the one or more ground selection lines as a voltage of a size less than or equal to the first set voltage;
determining the set voltage of the one or more dummy word lines as a voltage of a size that is less than or equal to a minimum value of the set voltage applied to the one or more ground selection lines and greater than a source voltage applied to the common source line; and
determining the set voltage of a common ground line as an off voltage that is less than the source voltage.

20. A memory device comprising:
a memory cell array including a plurality of cell strings that are stacked on a substrate and connected to a common source line in parallel; and
a control logic configured to perform control of the memory cell array,
wherein the memory cell array comprises:
the common source line, and
a plurality of word lines including:
one or more ground selection lines included in a first cell region, the one or more ground selection lines being configured to control a connection between the common source line and a plurality of string selection lines,
a plurality of main word lines included in a second cell region, the plurality of main word lines being configured to store data, and
one or more dummy word lines included in a dummy cell region disposed between the common source line and the first cell region,
the plurality of word lines being configured to connect elements among a plurality of elements included in the plurality of cell strings that are disposed at location levels with respect to the substrate to each other, and
wherein the control logic is configured to apply a voltage of a size determined based on a location level of each of the plurality of word lines with respect to the substrate to the each of the plurality of word lines.
